(19) United States
(12) Patent Application Publication
(10) Pub. No.: US 2026/0371715 A1
(43) Pub. Date: Nov. 19, 2026

(54) Circuit Device

(71) Applicant: SEIKO EPSON CORPORATION, Tokyo (JP)

(72) Inventor: Yasuharu KAWAI, Kofu (JP)

(21) Appl. No.: 19/374,295

(22) Filed: Oct. 30, 2025

(30) Foreign Application Priority Data
Oct. 31, 2024 (JP) 2024-191544

(51) Int. Cl. H10D 84/83; H02M 3/158; H03K 17/0812; H10D 62/10; H10D 62/17

(52) U.S. Cl. CPC H10D 84/835; H02M 3/158; H03K 17/08122; H10D 62/106; H10D 62/393

(57) ABSTRACT

A circuit device includes an N-type first DMOS transistor having an N-type drain region coupled to an inductor, and an N-type second DMOS transistor. The transistor includes a P-type body region, an N-type source region provided in the body region, and a P-type contact region provided in the body region. A width of the body region in a channel length direction of the first DMOS transistor is wider than a width of the body region in the channel length direction of the second DMOS transistor.

The present application is based on, and claims priority from JP Application Serial Number 2024-191544, filed Oct. 31, 2024, the disclosure of which is hereby incorporated by reference herein in its entirety.

### BACKGROUND

### 1. Technical Field

The present disclosure relates to a circuit device and the like.

### 2. Related Art

JP-A-2015-153937 discloses a circuit device in which a guard region for setting a substrate of the circuit device at a substrate potential is provided between a high-side transistor or a low-side transistor of a bridge circuit and a detection circuit. In JP-A-2015-153937, the guard region is provided to solve the problem that the substrate potential fluctuates due to switching operation of the bridge circuit.

JP-A-2015-153937 is an example of the related art.

However, with only the guard region, absorption of a negative surge generated by a counter electromotive force of an inductor is insufficient, and a defect caused by the negative surge may occur.

### SUMMARY

An aspect of the present disclosure relates to a circuit device including an N-type first DMOS transistor having an N-type first drain region coupled to an inductor, and an N-type second DMOS transistor, wherein the first DMOS transistor includes a P-type first body region, an N-type first source region provided in the first body region, and a P-type first contact region provided in the first body region, the second DMOS transistor includes a P-type second body region, an N-type second source region provided in the second body region, and a P-type second contact region provided in the second body region, and a width of the first body region in a channel length direction of the first DMOS transistor is wider than a width of the second body region in the channel length direction of the second DMOS transistor.

### BRIEF DESCRIPTION OF THE DRAWINGS

FIG. 1 shows an example of a circuit configuration of a circuit device according to an embodiment.

FIG. 2 shows an operation of a bridge circuit.

FIG. 3 shows the operation of the bridge circuit.

FIG. 4 shows a plan view and a cross-sectional view illustrating configurations of DMOS transistors.

FIG. 5 shows a plan view and a cross-sectional view illustrating the configuration of the DMOS transistor.

FIG. 6 shows a problem caused by a negative surge.

FIG. 7 is a plan view showing a detailed configuration of the DMOS transistor.

FIG. 8 is a plan view showing the detailed configuration of the DMOS transistor.

FIG. 9 is a plan view showing the detailed configuration of the DMOS transistor.

FIG. 10 shows a configuration example of a circuit device using the DMOS transistors.

FIG. 11 shows a configuration example of parallel coupling of the DMOS transistors.

FIG. 12 shows a configuration example of a DMOS transistor including a plurality of unit transistors.

FIG. 13 is a plan view showing an arrangement example of the DMOS transistors and a pad.

FIG. 14 is a plan view showing another arrangement example of the DMOS transistors and the pad.

### DESCRIPTION OF EMBODIMENTS

An embodiment will hereinafter be described. Note that the present embodiment to be described below do not unduly limit the present disclosure described in What is claimed is. Not all configurations described in the embodiment are essential component elements.

### 1. Circuit Device

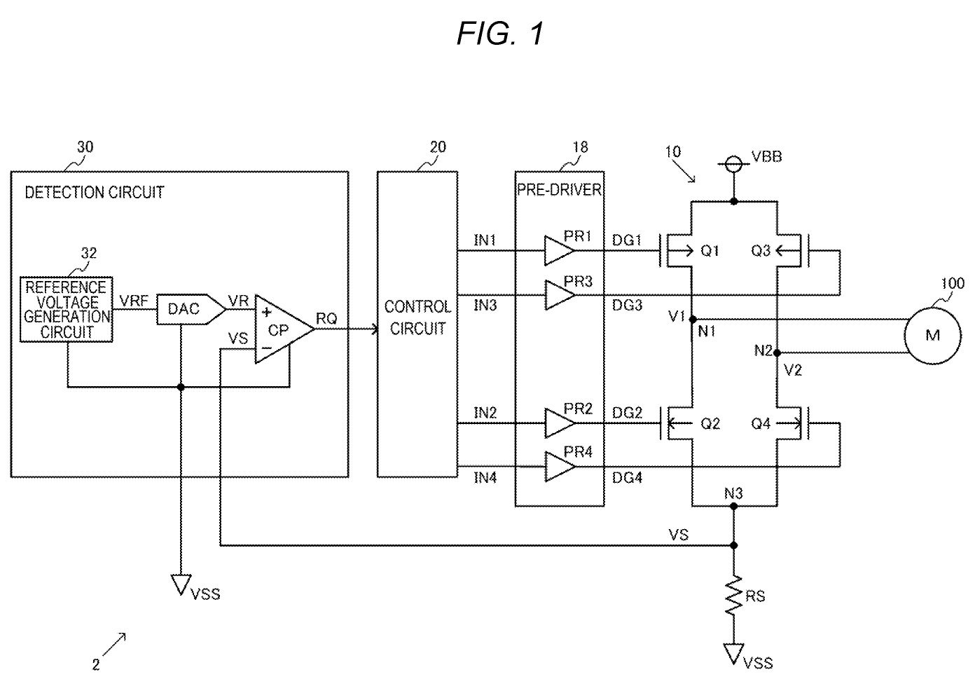

FIG. 1 shows an example of a circuit configuration of a circuit device 2 of the present embodiment. The circuit device 2 in FIG. 1 includes a bridge circuit 10, a pre-driver 18, a control circuit 20, and a detection circuit 30. The circuit device 2 of the present embodiment is not limited to the circuit configuration shown in FIG. 1, but various modifications such that part of the component elements thereof are omitted or another component element is added thereto can be made. For example, FIG. 1 shows a case where the circuit device 2 is a motor driver that drives a motor 100, but the circuit device 2 of the present embodiment may be a circuit such as a switching regulator that converts a direct-current voltage into a different direct-current voltage using an inductor.

The bridge circuit 10 includes high-side transistors Q1 and Q3 and low-side transistors Q2 and Q4. The bridge circuit 10 is a circuit that outputs a drive current to the motor 100 as an inductor and has an H-bridge circuit configuration in FIG. 1. The high-side transistors Q1 and Q3 are, for example, P-type transistors of a first conductivity type, and the low-side transistors Q2 and Q4 are, for example, N-type transistors of a second conductivity type. The high-side transistor is a transistor coupled to a higher potential power supply side than the low-side transistor. The low-side transistor is a transistor coupled to a lower potential power supply side than the high-side transistor. All of the transistors Q1, Q2, Q3, and Q4 may be N-type transistors. Body diodes as parasitic diodes (not illustrated) are present between the sources and the drains of Q1, Q2, Q3, and Q4.

The sources of the high-side transistors Q1 and Q3 are coupled to the node of a high-potential-side power supply voltage VBB. The sources of the low-side transistors Q2 and Q4 are coupled to a node N3 to which one end of a sense resistor RS is coupled.

The drain of the transistor Q1 and the drain of the transistor Q2 are coupled to a node N1 coupled to one end of the external motor 100. The drain of the transistor Q3 and the drain of the transistor Q4 are coupled to a node N2 coupled to the other end of the motor 100. The node N1 is an output node of an output signal V1, and the node N2 is an output node of an output signal V2.

The detection circuit 30 detects a charge current in a charge period by detecting, for example, a voltage VS at one end of the sense resistor RS. For example, the detection circuit 30 detects the charge current by detecting a voltage difference between the voltage VS and a low-potential-side power supply voltage VSS. VSS is, for example, GND, the ground voltage.

The detection circuit 30 includes a reference voltage generation circuit 32, a D/A conversion circuit DAC, and a comparison circuit CP. The reference voltage generation circuit 32 generates a constant reference voltage VRF. The D/A conversion circuit DAC receives the reference voltage VRF and generates a reference voltage VR that varies based on setting data. In the comparison circuit CP, the reference voltage VR is input to a first input terminal, which is a non-inverting input terminal, the voltage VS as the voltage at one end of the sense resistor RS is input to a second input terminal, which is an inverting input terminal, and a detection result signal RQ is output.

The control circuit 20 performs on/off control of the high-side transistors Q1 and Q3 and the low-side transistors Q2 and Q4 based on the detection result in the detection circuit 30. Specifically, control signals IN1, IN2, IN3, and IN4, which are PWM signals, are generated based on the detection result signal RQ from the detection circuit 30. The length of the charge period is controlled by these control signals IN1, IN2, IN3, and IN4.

The pre-driver 18 buffers the control signals IN1, IN2, IN3, and IN4 from the control circuit 20, and outputs drive signals DG1, DG2, DG3, and DG4 to the gates of the transistors Q1, Q2, Q3, and Q4. The pre-driver 18 includes driver circuits PR1, PR2, PR3, and PR4 that buffer the control signals IN1, IN2, IN3, and IN4 and output the drive signals DG1, DG2, DG3, and DG4.

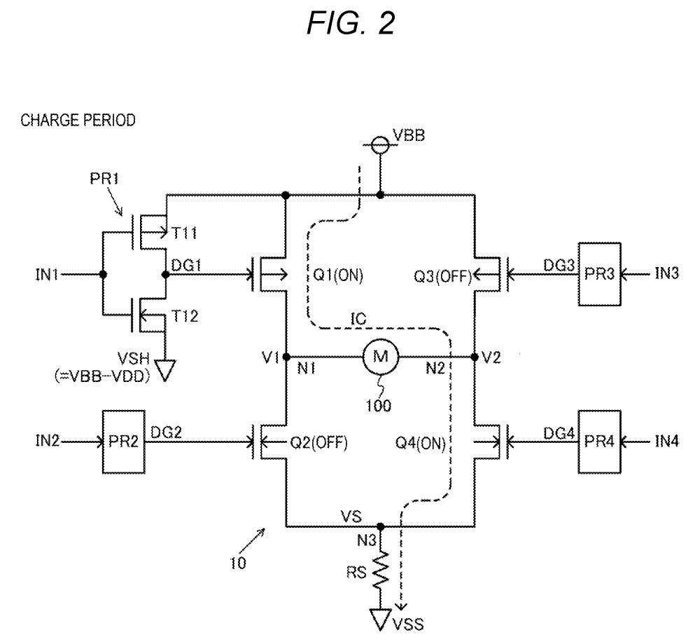

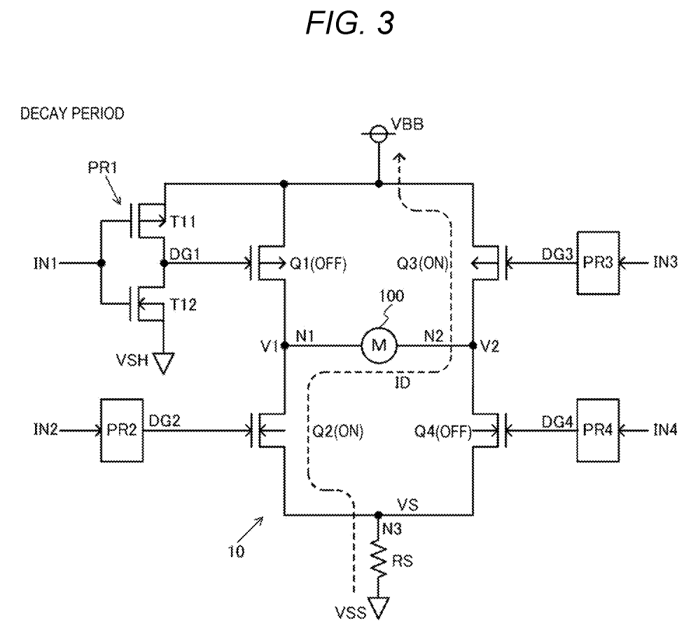

Next, the operation of the bridge circuit 10 will be described with reference to FIGS. 2 and 3. When the driving of the motor 100 is started, the charge period illustrated in FIG. 2 starts, the transistors Q1 and Q4 are turned on, and the transistors Q2 and Q3 are turned off. Accordingly, a charge current IC, which is a drive current, flows from the node of the high-potential-side VBB to the node of the low-potential-side VSS (GND) via the transistor Q1, the motor 100, and the transistor Q4.

When the drive current of the motor 100 reaches a chopping current, the period is switched to a decay period. Specifically, when the drive current increases and the voltage VS of the node N3 exceeds the reference voltage VR, the period is switched to the decay period.

When the period is switched to the decay period, as shown in FIG. 3, the transistors Q2 and Q3 are turned on, and the transistors Q1 and Q4 are turned off. Accordingly, a decay current ID, which is the drive current, flows from the node of VSS to the node of VBB via the transistor Q2, the motor 100, and the transistor Q3. In the decay period, the drive current of the motor 100 decreases with time. Then, the control circuit 20 detects that a predetermined time has elapsed from the start of the decay period using, for example, a timer, and switches from the decay period to the charge period. In the charge period, when the drive current of the motor 100 increases and reaches the chopping current, the period is switched to the decay period again. Thereafter, the operation is repeated, thereby performing control such that the chopping current, which is a peak current of the drive current, becomes constant to keep the rotation speed of the motor 100 constant. Specifically, the control circuit 20 controls pulse widths of PWM signals IN1 to IN4 so that the chopping current becomes constant, and on/off of the transistors Q1 to Q4 is controlled based on the PWM signals.

Although a decay operation called fast decay is shown in FIG. 3, a decay operation called slow decay may be performed. In slow decay, the transistors Q2 and Q4 are turned on, and the transistors Q1 and Q3 are turned off. Accordingly, a decay current flows from the node of VSS to the node of VSS via the transistor Q2, the motor 100, and the transistor Q4. In FIGS. 1, 2, and 3, the case where the bridge circuit 10 is the H-bridge type circuit has been described, but the present embodiment is not limited thereto, and the bridge circuit 10 may be a half-bridge type circuit. In this case, the transistors Q3 and Q4 are not provided as the bridge circuit 10, but the transistors Q1 and Q2 are provided. In the above description, the case where the circuit device 2 is the motor driver that drives the motor 100 has been described as an example, but the object to be driven by the circuit device 2 of the present embodiment is not limited to the motor 100, and various elements and devices having inductors such as a coil can be driven by the circuit device.

### 2. DMOS Transistors

In the circuit device 2 of the motor driver as illustrated in FIG. 1, a high voltage is applied between the drain and the source of each of the transistors Q1, Q2, Q3, and Q4 of the bridge circuit 10. For this reason, high-voltage DMOS (Double-diffused MOSFET) transistors are used as the transistors Q1, Q2, Q3, and Q4. The DMOS transistor is a transistor having a structure in which a P-type region and an N-type region serving as a source are doubly diffused on a surface of an N-type region formed on a semiconductor substrate.

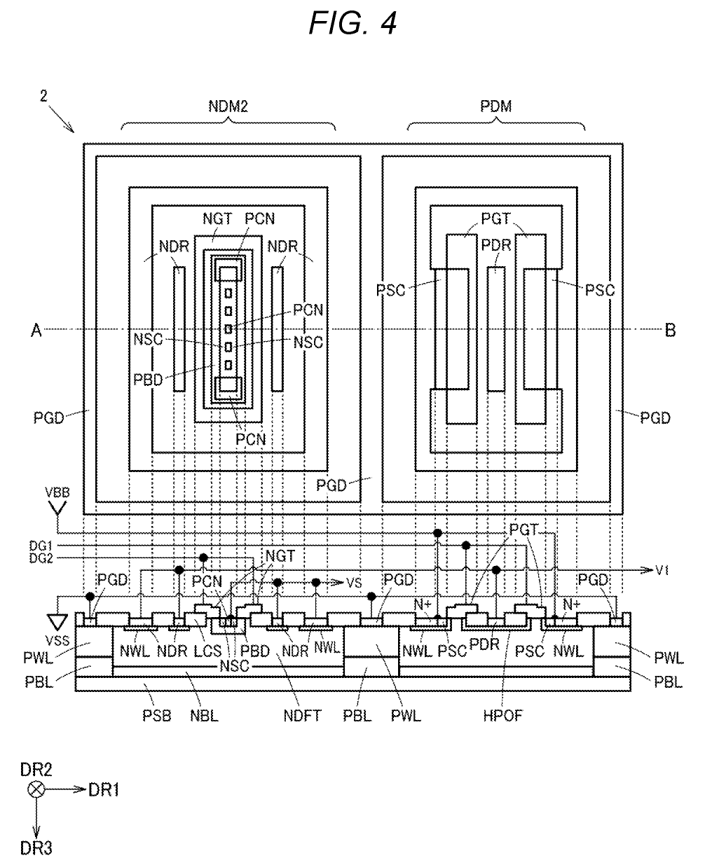

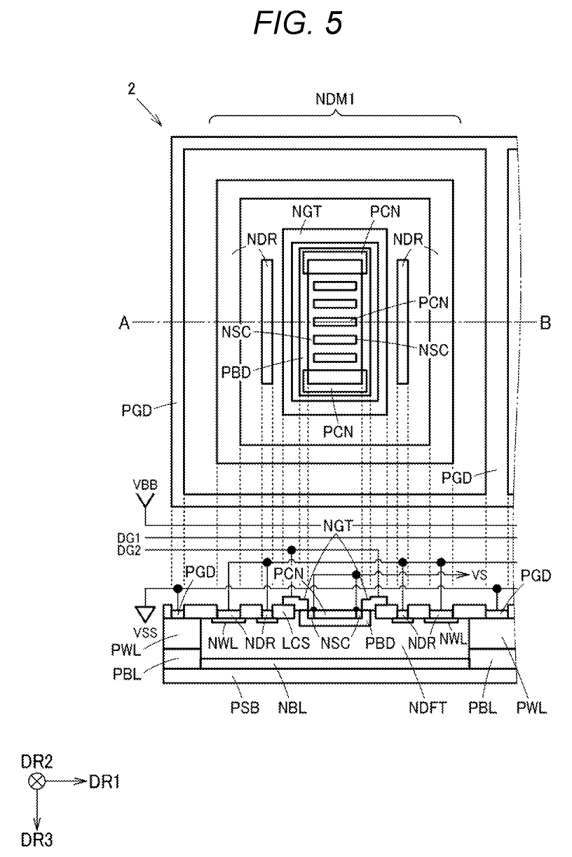

FIG. 4 shows a plan view and a cross-sectional view illustrating a configuration example of a P-type DMOS transistor PDM and an N-type DMOS transistor NDM2. FIG. 5 shows a plan view and a cross-sectional view illustrating a configuration example of an N-type DMOS transistor NDM1. Specifically, the transistor NDM2 in FIG. 4 is an N-type second DMOS transistor, and the transistor NDM1 in FIG. 5 is an N-type first DMOS transistor. The cross-sectional views of FIGS. 4 and 5 show the cross sections along A-B in the plan views of FIGS. 4 and 5, respectively. Further, directions parallel to the plane of a substrate PSB of the circuit device 2 are DR1 and DR2, and a direction orthogonal to the substrate PSB is DR3. The directions DR1 and DR2 are orthogonal to each other. The plan views of FIGS. 4 and 5 are plan views in the direction DR3 orthogonal to the substrate PSB.

Hereinafter, a direction in which a circuit is formed with respect to the substrate PSB is referred to as "upper", and the opposite direction is referred to as "lower". In addition, FIGS. 4 and 5 illustrate a coupling configuration when the high-side transistor Q1 in FIG. 1 is configured with the P-type DMOS transistor PDM and the low-side transistor Q2 is configured with the N-type DMOS transistor NDM1 or transistor NDM2.

As shown in FIGS. 4 and 5, an N-type (N+) buried layer NBL is formed on the P-type substrate PSB. An N-type (N-) drift region NDFT serving as a drift layer is formed on the N-type buried layer NBL. The NDFT is also called a deep N-well. A body region PBD which is a P-type (P-) impurity region is formed in the N-type drift region NDFT, and source regions NSC of the N-type DMOS transistors NDM1 and NDM2 are formed in the body region PBD. The source region NSC is an N-type (N+) impurity region. The impurity region is, for example, a diffusion region. In the P-type body region PBD, a contact region PCN, which is a P-type (P+) impurity region, is also formed. This contact region PCN is coupled to the node N3 of the voltage VS, which is one end side of the sense resistor RS of FIG. 1, whereby the body region PBD is also electrically coupled to the node N3 of the voltage VS.

Further, an N-type (N-) well NWL is formed in the N-type drift region NDFT, and drain regions NDR of the N-type DMOS transistors NDM1 and NDM2 are formed on the well NWL. The drain region NDR is an N-type (N+) impurity region. The drain region NDR is coupled to the node N1 of the output signal V1 in FIG. 1.

An insulating layer LCS called LOCOS (local oxidation of silicon) is formed in the N-type drift region NDFT. Further, gate layers NGT of the DMOS transistors NDM1 and NDM2 are also formed therein, and a node to which the drive signal DG2 in FIG. 1 is output is coupled to the gate layers NGT. The portions of the P-type body region PBD below the gate layers NGT serve as channel regions of the transistors NDM1 and NDM2.

Also in the P-type DMOS transistor PDM, a drain region PDR, which is a P-type (P+) impurity region, is formed in a P-type impurity region HPOF. On the N-type (N-) well NWL, a source region PSC, which is a P-type (P+) impurity region, and an N+ region, which is an N-type (N+) impurity region, are formed. Further, gate layers PGT of the transistor PDM are formed thereon. The drain region PDR is coupled to the node N1 of the output signal V1, and the source region PSC and the N+ region are coupled to the node to which VBB as the high-potential-side power supply voltage is applied.

In FIGS. 4 and 5, guard regions PGD coupled to the node of VSS as the GND are provided. The guard region PGD is a P-type (P+) impurity region. P-side wells PWL are formed below the guard regions PGD, and P-type buried layers PBL formed on the substrate PSB are provided below the wells PWL. Accordingly, the potential of the P-type substrate PSB is set to VSS, and stabilization of the substrate potential is realized. In FIGS. 4 and 5, the guard regions PGD for stabilizing the substrate potential are formed so as to surround the peripheries of the respective transistors NDM1, NDM2, and PDM.

### 3. Negative Surge

In a circuit using an inductor such as a motor driver or a switching regulator, a negative surge is generated due to a counter electromotive force of the inductor during operation, and the negative surge causes a malfunction of the circuit. For example, in the bridge circuit 10 of the motor driver in FIG. 1, as shown in FIGS. 2 and 3, current control to repeat a charge operation and a decay operation of the drive current of the motor 100 is performed. When the current flowing through the motor 100 is cut off, a counter electromotive force is generated due to characteristics of the inductive component and generates a negative surge.

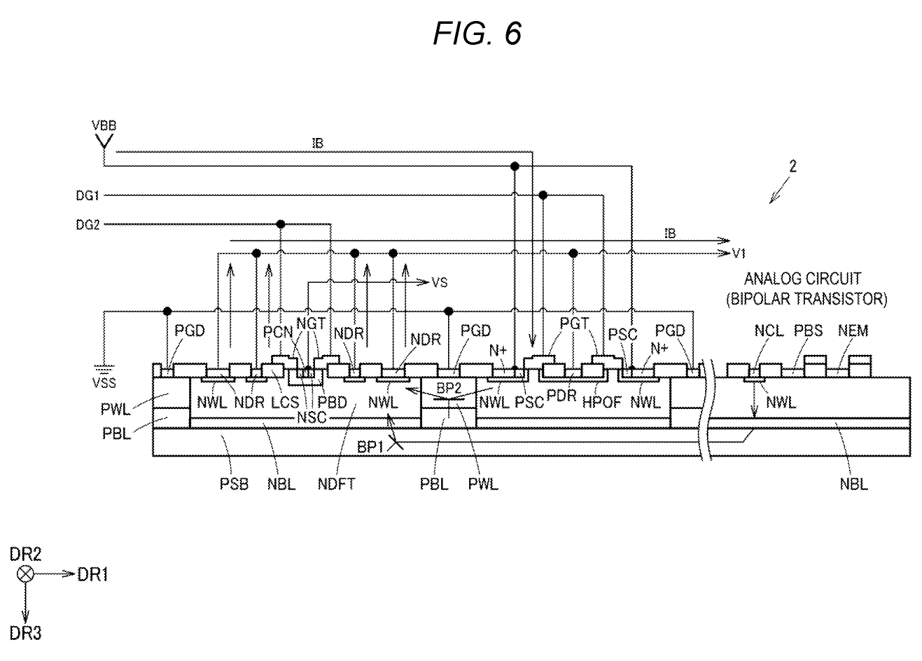

For example, when the transistor Q1 is switched from on to off at the time of switching from the charge period in FIG. 2 to the decay period in FIG. 3, a negative surge in which a potential of the node N1 of the drain of the transistor Q2 changes to a negative potential is generated by the amount of the counter electromotive force generated in the motor 100. The negative surge flows in from the drain of the N-type DMOS transistor Q2, but when the negative surge cannot be absorbed by, for example, the guard regions PGD set for VSS, parasitic bipolar transistors BP1 and BP2 as shown in FIG. 6 are formed.

For example, in FIG. 6, a bipolar transistor having an N-type collector region NCL, a P-type base region PBS, and an N-type emitter region NEM is provided as an analog circuit. The parasitic bipolar transistor BP1 in FIG. 6 is an npn bipolar transistor formed with the N-type collector region NCL of the bipolar transistor of the analog circuit, the P-type substrate PSB, and the N-type drain region NDR of the N-type DMOS. When the N-type drain region NDR has a negative potential due to a negative surge caused by the counter electromotive force and the base-emitter voltage of the bipolar transistor BP1 exceeds a predetermined voltage VBE, the bipolar transistor BP1 is turned on. When the bipolar transistor BP1 is turned on by the negative surge, noise of the negative surge propagates to the analog circuit, and a problem such as fluctuations in characteristics of the analog circuit occurs.

In this case, in order to reduce the adverse effect of the negative surge noise, there is a method of increasing the distance between the bridge circuit 10, which is a negative surge source, and the analog circuit. However, since the magnitude of the negative surge noise is proportional to the drive current of the motor 100, the negative surge noise increases as the drive current increases. Therefore, in the method of increasing the distance from the negative surge source as described above, it is necessary to sufficiently increase the distance between the negative surge source and the analog circuit, for example, increase the distance from the negative surge source by several hundreds of micrometers according to the maximum drive current of the motor 100. Accordingly, a problem of increase in chip area of the circuit device is caused.

At the time of switching from the charge period to the decay period, the P-type transistor Q1 of the bridge circuit 10 is turned off from on, and the N-type transistor Q2 is turned on from off. Accordingly, when the parasitic npn bipolar transistor BP2 between the P-type DMOS and the N-type DMOS is turned on by a negative surge, as illustrated in FIG. 6, a current IB flows from the VBB node to the VSS side via the bipolar transistor BP2 that is on and the N-type transistor Q2, and a problem such as a short circuit between power supplies occurs although the sense resistor RS is present.

Therefore, in the present embodiment, a method of disposing a portion that absorbs the negative surge near an inflow portion of the negative surge is adopted. Specifically, as the N-type DMOS transistor having the drain region NDR to which an inductor such as the motor 100 is coupled, as illustrated in FIG. 5, the transistor NDM1 having the body region PBD wider in a channel length direction is used. According to the configuration, the body diode in the body region PBD serves as a negative surge absorbing portion and can absorb the negative surge. Therefore, the negative surge generated in the drain region NDR of the transistor NDM1 can be absorbed by the body diode in the body region PBD, and the propagation of the negative surge noise can be suppressed without increasing the distance from another circuit block such as an analog circuit. In addition, the occurrence of the problem of the short circuit between the power supplies described in FIG. 6 can be suppressed.

Specifically, the circuit device 2 of the present embodiment includes the N-type DMOS transistor NDM1 illustrated in FIG. 5 and the N-type DMOS transistor NDM2 illustrated in FIG. 4. That is, as the transistors forming the circuit device 2, the N-type DMOS transistor NDM1 in FIG. 5 and the N-type DMOS transistor NDM2 in FIG. 4 are provided. The transistor NDM1 is a first DMOS transistor, and the transistor NDM2 is a second DMOS transistor. The drain region NDR of the transistor NDM1 is coupled to an inductor such as the motor 100. The drain region NDR of the transistor NDM2 may be coupled to the inductor or not.

As shown in FIG. 5, the transistor NDM1 as the first DMOS transistor includes the P-type body region PBD, the N-type source region NSC provided in the body region PBD, and the P-type contact region PCN provided in the body region PBD. The body region PBD, the source region NSC, and the contact region PCN of the transistor NDM1 are a first body region, a first source region, and a first contact region, respectively. The contact region PCN is a P-type impurity region and can also be called a P-type tap region. The body region PBD is electrically coupled to the VS node, which is a source node, by the contact region PCN.

As illustrated in FIG. 4, the transistor NDM2 as the second DMOS transistor includes the P-type body region PBD, the N-type source region NSC provided in the body region PBD, and the P-type contact region PCN provided in the body region PBD. The body region PBD, the source region NSC, and the contact region PCN of the transistor NDM2 are a second body region, a second source region, and a second contact region, respectively.

In the present embodiment, the width of the body region PBD in the channel length direction of the transistor NDM1 in FIG. 5 is wider than the width of the body region PBD in the channel length direction of the transistor NDM2 in FIG. 4. Here, the channel length direction is the direction of the channel lengths of the transistors NDM1 and NDM2, and is the direction DR1 in FIGS. 4 and 5. In contrast, a channel width direction is the direction DR2 in FIGS. 4 and 5.

As described above, in the transistor NDM1 of FIG. 5, the width of the body region PBD in the channel length direction is wider than that of the transistor NDM2 of FIG. 4. Therefore, for example, the area of PN junction of the body diode between the P-type body region PBD and the N-type drift region NDFT in the transistor NDM1 of FIG. 5 is larger than that in the transistor NDM2 of FIG. 4. The body diodes are diodes having the N-type drain regions NDR (and NDFT) of the transistors NDM1 and NDM2 as cathodes and the P-type body regions PBD (and PCN) as anodes. In FIGS. 4 and 5, in addition to the body diodes, body diodes having the N-type drain regions NDR (and NDFT) as cathodes and the P-type guard regions PGD (and PWL, PBL, and PSB) as anodes are present. However, the body diode formed with the P-type guard region PGD may not sufficiently absorb the negative surge generated in the drain region NDR.

In this regard, in the present embodiment, in the body diode formed with the body region PBD provided in parallel with the body diode formed with the guard region PGD, the width of the body region PBD in the direction DR1 as the channel length direction is increased as illustrated in the transistor NDM1 of FIG. 5. The DMOS transistor NDM1 having the wider body region PBD is used as the low-side transistors Q2 and Q4 of the bridge circuit 10 in FIG. 1.

According to the configuration, even when a negative surge due to the counter electromotive force of the inductor is generated in the drains of the transistors Q2 and Q4, the negative surge can be sufficiently absorbed by the body diodes due to the body regions PBD having the wider PN junction areas. That is, by providing the body diode of the wider body region PBD in the vicinity of the inflow portion of the negative surge, an opening of an absorption path of the negative surge is widened, and the relationship of the inflow amount of the negative surge current ≤ the absorption amount of the negative surge current holds. Thus, the negative surge is absorbed by the body diode of the wider body region PBD before the adverse effect due to the negative surge is diffused. According to the configuration, the occurrence of problems that the negative surge noise adversely affects another circuit such as an analog circuit due to the parasitic bipolar transistor BP1 and a short circuit occurs between the power supplies due to the parasitic bipolar transistor BP2 as described with reference to FIG. 6 can be suppressed.

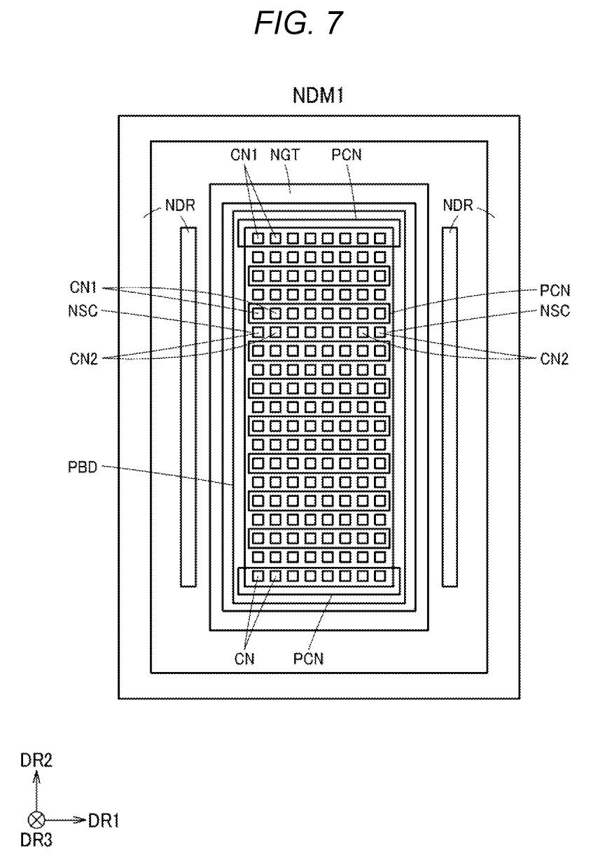

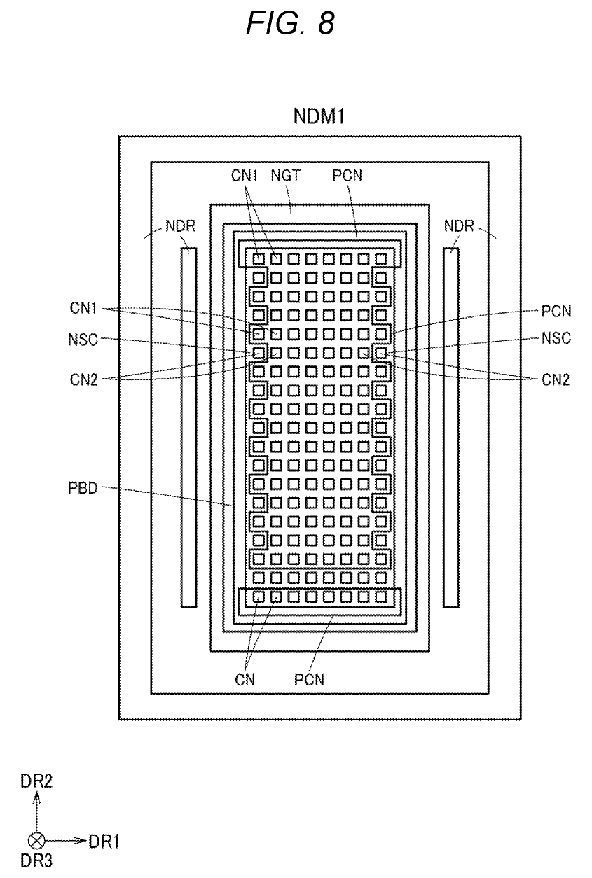

FIGS. 7 and 8 are plan views illustrating a detailed configuration example of the transistor NDM1 as the N-type first DMOS transistor. FIGS. 7 and 8 show an arrangement example of contacts CN1 provided in the contact regions PCN and contacts CN2 provided in the source regions NSC. The P-type contact region PCN is coupled to a signal line of VS, which is a source signal line, via the contact CN1. The N-type source region NSC is coupled to the signal line of VS as the source signal line via the contact CN2.

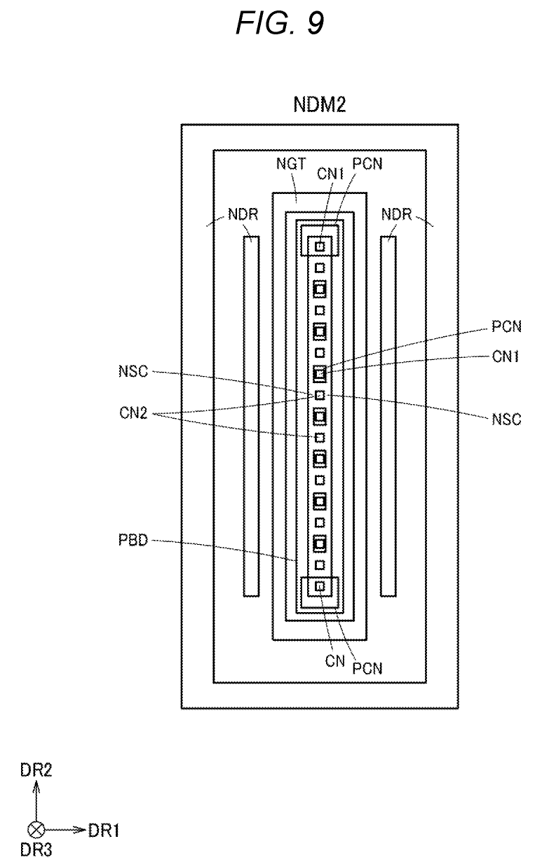

FIG. 9 is a plan view illustrating a detailed configuration example of the transistor NDM2 as the N-type second DMOS transistor. FIG. 9 also shows an arrangement example of the contacts CN1 provided in the contact regions PCN and the contacts CN2 provided in the source regions NSC.

As illustrated in FIGS. 7 and 8, in the transistor NDM1, the width of the body region PBD in the direction DR1 as the channel length direction is wider than that of the transistor NDM2 in FIG. 9. Therefore, as illustrated in FIGS. 7 and 8, in the transistor NDM1, a larger number of contacts CN1 and CN2 can be disposed as compared with the transistor NDM2 of FIG. 9. According to the configuration, in the transistor NDM1, since the number of the contacts CN1 and CN2 is larger, contact resistances between metal layers and impurity regions in the contacts CN1 and CN2 are lower, and the negative surge current can be more effectively absorbed.

As described above, the circuit device 2 of the present embodiment includes the N-type DMOS transistor NDM1 having the drain region NDR coupled to the inductor and the N-type DMOS transistor NDM2. As illustrated in FIG. 5, the transistor NDM1 includes the P-type body region PBD, the N-type source region NSC provided in the body region PBD, and the P-type contact region PCN provided in the body region PBD. As illustrated in FIG. 4, the transistor NDM2 includes the P-type body region PBD, the N-type source region NSC provided in the body region PBD, and the P-type contact region PCN provided in the body region PBD. The source region NSC and the contact region PCN are electrically coupled to each other. As illustrated in FIGS. 5 and 4, the width of the body region PBD in the channel length direction of the transistor NDM1 as the first DMOS transistor is wider than the width of the body region PBD in the channel length direction of the transistor NDM2 as the second DMOS transistor.

According to the configuration, even when a negative surge is generated in the drain region NDR of the transistor NDM1 due to the counter electromotive force of the inductor, the negative surge can be effectively absorbed by the body diode formed with the wider body region PBD. As a result, the adverse effect of the negative surge noise on another circuit such as an analog circuit can be suppressed, the distance from the other circuit is not necessarily increased, and the area of the circuit device 2 can be reduced. The occurrence of the problem of a short circuit between the power supplies due to parasitic bipolar transistor can be suppressed.

As illustrated in FIG. 5, the width of the contact region PCN in the channel length direction of the transistor NDM1 is wider than the width of the contact region PCN in the channel length direction of the transistor NDM2. That is, the width of the contact region PCN of the transistor NDM1 in the direction DR1 is wider than that of the transistor NDM2. According to the configuration, as illustrated in FIGS. 7 and 8, a larger number of contacts can be disposed in the contact region PCN of the transistor NDM1 or the like than in the transistor NDM2 of FIG. 9. Accordingly, the contact resistance between the metal layer and the impurity region in the contact is reduced, and the negative surge can be absorbed more effectively. Therefore, the occurrence of the problem caused by the negative surge can be further suppressed.

As illustrated in FIGS. 4 and 5, the circuit device 2 includes the P-type substrate PSB on which the transistor NDM1 and the transistor NDM2 are provided. The P-type body region PBD of the transistor NDM1 is provided in the N-type drift region NDFT provided between the transistor NDM1 and the P-type substrate PSB. The P-type body region PBD of the transistor NDM2 is provided in the N-type drift region NDFT provided between the transistor NDM2 and the P-type substrate PSB. A first drift region which is the drift region NDFT provided with the body region PBD of the transistor NDM1 and a second drift region which is the drift region NDFT provided with the body region PBD of the transistor NDM2 may be the same region. The drift region NDFT is an N-type well and is also called, for example, a deep N-well.

According to the configuration, the negative surge can be absorbed by the body diode formed by the PN junction between the P-type body region PBD and the N-type drift region NDFT. Since the P-type body region PBD forming the body diode is the region wider in the channel length direction, the area of the PN junction of the body diode can be increased, and the negative surge can be effectively absorbed.

The transistor NDM1 in FIG. 5 is the low-side transistor of the bridge circuit 10 that drives the inductor. For example, in FIG. 1, the bridge circuit 10 drives the motor 100 as the inductor. In this case, the transistor NDM1 as the N-type first DMOS transistor is used as the low-side N-type transistors Q2 and Q4 of the bridge circuit 10.

According to the configuration, the negative surge generated by the counter electromotive force of the inductor driven by the bridge circuit 10 can be effectively absorbed by the body diode formed with the body region PBD of the transistor NDM1. As a result, problems of deterioration of performance characteristics of other circuits due to a negative surge, an increase in circuit area due to an increase in distance from other circuits, and a short circuit between power supplies due to parasitic bipolar transistor can be suppressed. As will be described later, part of transistors forming the low-side transistors Q2 and Q4 may be formed with the transistor NDM1, and the other transistors may be formed with the transistor NDM2.

### 4. Application Example of DMOS Transistor

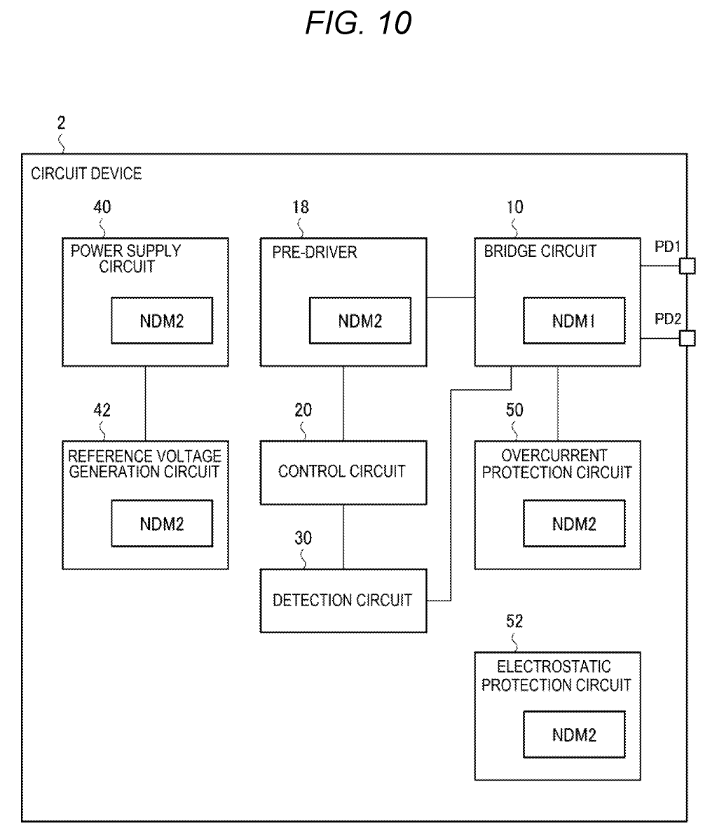

Next, an application example of the DMOS transistor in the circuit device 2 will be described in detail. FIG. 10 shows a configuration example of the circuit device 2 using the DMOS transistor. The circuit device 2 in FIG. 10 includes the bridge circuit 10, the pre-driver 18, the control circuit 20, the detection circuit 30, a power supply circuit 40, a reference voltage generation circuit 42, an overcurrent protection circuit 50, and an electrostatic protection circuit 52.

The bridge circuit 10 drives the motor 100 as the inductor as described in FIG. 1. The bridge circuit 10 includes the high-side transistors Q1 and Q3 and the low-side transistors Q2 and Q4. The drive current is output via pads PD1 and PD2 coupled to both ends of the motor 100. The detection circuit 30 receives the voltage VS at one end of the sense resistor RS and outputs the detection result signal RQ. The control circuit 20 performs the on/off control of the high-side transistors Q1 and Q3 and the low-side transistors Q2 and Q4 based on the detection result in the detection circuit 30. The pre-driver 18 buffers the control signal from the control circuit 20 and outputs the drive signal to the gates of the transistors Q1, Q2, Q3, and Q4.

The power supply circuit 40 is supplied with, for example, an external power supply voltage, and supplies various power supply voltages for each circuit inside the circuit device 2 to each circuit. The reference voltage generation circuit 42 generates a reference voltage used in various circuits such as an analog circuit of the circuit device 2. For example, the reference voltage generation circuit 42 generates the reference voltage using a bandgap reference circuit or the like. The power supply circuit 40 generates a power supply voltage to be supplied to each circuit of the circuit device 2 based on, for example, the reference voltage generated by the reference voltage generation circuit 42.

For example, when an overcurrent drive current flows in the bridge circuit 10, the overcurrent protection circuit 50 detects the overcurrent drive current and controls the bridge circuit 10 and the like so that the overcurrent drive current does not flow. For example, the overcurrent protection circuit 50 performs an operation of controlling an overcurrent exceeding the maximum current value defined by the specification of the circuit device 2 not to flow.

The electrostatic protection circuit 52 is a circuit that protects an internal circuit of the circuit device 2 from a surge of ESD (Electro-Static Discharge) applied to a pad, which is an external coupling terminal of the circuit device 2. For example, the electrostatic protection circuit 52 is incorporated between the pad and the internal circuit, and operates so that the ESD surge is not applied to the internal circuit to protect the internal circuit.

In FIG. 10, the transistor NDM1 as the first DMOS transistor is used as the transistor forming the bridge circuit 10. Specifically, the low-side transistors Q2 and Q4 of the bridge circuit 10 are formed with the transistor NDM1 having the body region PBD wider in the channel length direction. As will be described later, only part of the transistors Q2 and Q4 may be formed with the transistor NDM1.

In contrast, the transistor NDM2 as the second DMOS transistor is used as the transistor forming the pre-driver 18. For example, as a transistor that needs to have a high withstand voltage in the pre-driver 18, the transistor NDM2 having the narrower body region PBD than that of the transistor NDM1 is used. For example, the pre-driver 18 includes a level shifter for outputting a control signal at an appropriate voltage level to the bridge circuit 10, and the high-voltage DMOS transistor NDM2 is used as a transistor forming the level shifter.

Further, the transistor NDM2 having the narrower body region PBD than that of the transistor NDM1 is used as a high-voltage transistor forming the power supply circuit 40 and the reference voltage generation circuit 42. For example, the power supply circuit 40 and the reference voltage generation circuit 42 have analog circuits that generate the power supply voltage and the reference voltage based on the power supply voltage VBB, which is a high voltage, and the DMOS transistor NDM2 is used as a high-voltage transistor forming the analog circuits.

Further, the transistor NDM2 having the narrower body region PBD than that of the transistor NDM1 is used as a high-voltage transistor forming the overcurrent protection circuit 50 and the electrostatic protection circuit 52. For example, the overcurrent protection circuit 50 and the electrostatic protection circuit 52 have protection circuits against a high voltage. The DMOS transistor NDM2 is used as a high-voltage transistor forming the protection circuit.

That is, the transistor NDM1 in FIG. 5 has the wider body region PBD, and thus there is an advantage that the negative surge can be effectively absorbed. However, the transistor NDM1 in FIG. 5 has the wider body region PBD, and thus there is a disadvantage that the layout area of the circuit becomes larger than that of the transistor NDM2 in FIG. 4.

Therefore, for a high-voltage transistor of a circuit that is considered not to be adversely affected by a negative surge, a normal DMOS transistor NDM2 having the narrower body region PBD is used instead of the transistor NDM1. For example, the transistor NDM2 having the narrower body region PBD is used as a DMOS transistor having a drain region to which the inductor is not coupled. For example, in FIG. 10, the transistor NDM1 having the wider body region PBD is used as the DMOS transistor forming the bridge circuit 10 having the drain region to which the inductor is coupled. Accordingly, the adverse effect due to a negative surge can be suppressed. In contrast, the transistor NDM2 having the narrower body region PBD is used as the DMOS transistor forming the pre-driver 18, the power supply circuit 40, the reference voltage generation circuit 42, the overcurrent protection circuit 50, and the electrostatic protection circuit 52. Accordingly, the increase in the circuit area due to the width of the body region PBD can be suppressed. Therefore, both the adverse effect due to the inflow of the negative surge current and the increase in the circuit area can be suppressed.

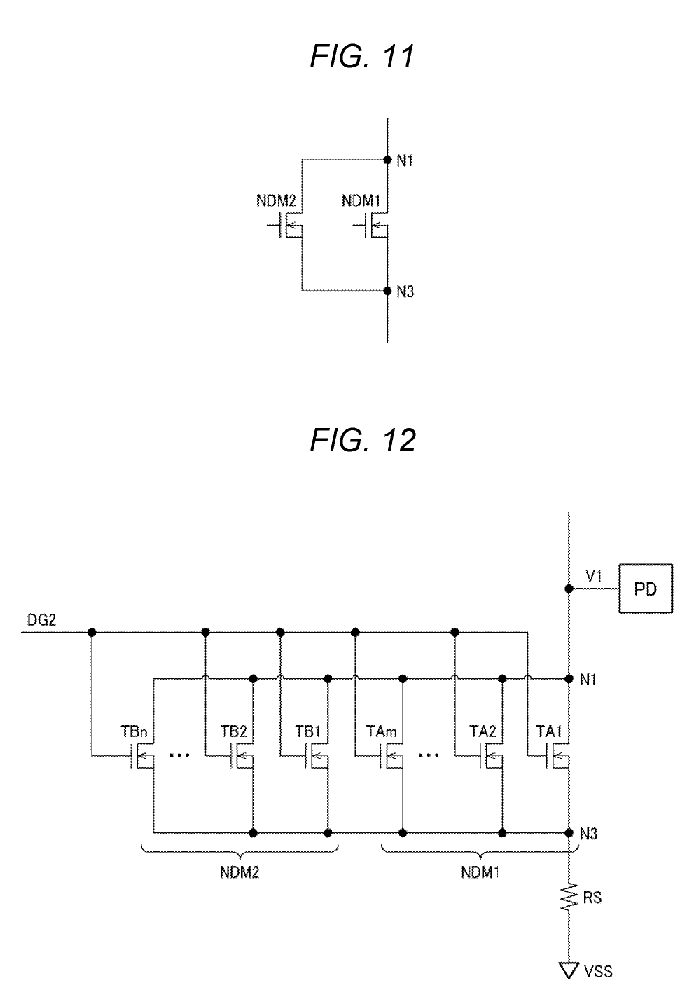

In the present embodiment, the transistor NDM2 as the second DMOS transistor may be a transistor coupled in parallel to the transistor NDM1 as the first DMOS transistor. For example, in FIG. 11, the transistor NDM1 and the transistor NDM2 are coupled in parallel between the node N1 and the node N3. For example, the drain region of the transistor NDM1 and the drain region of the transistor NDM2 are coupled to the node N1, and the source region NSC of the transistor NDM1 and the source region NSC of the transistor NDM2 are coupled to the node N3.

According to the configuration, the negative surge generated at the node N1 of the drain can be absorbed by the transistor NDM1 having the wider body region PBD. The transistor NDM2 having the narrower body region PBD is used as the DMOS transistor coupled in parallel to the transistor NDM1, and thus an unnecessary increase in circuit area can be suppressed.

Specifically, as illustrated in FIG. 12, a plurality of unit transistors TA1 to TAm, each of which is the DMOS transistor NDM1, and a plurality of unit transistors TB1 to TBn, each of which is the DMOS transistor NDM2, are provided. Here, m and n are integers of 2 or more. The unit transistors TA1 to TAm are first unit transistors, and the unit transistors TB1 to TBn are second unit transistors. In FIG. 12, the plurality of unit transistors TA1 to TAm and the plurality of unit transistors TB1 to TBn are coupled in parallel. For example, the drains of the unit transistors TA1 to TAm and the drains of the unit transistors TB1 to TBn are coupled to the node N1, and the sources of the unit transistors TA1 to TAm and the sources of the unit transistors TB1 to TBn are coupled to the node N3. For example, the low-side transistor Q2 in FIG. 1 includes the unit transistors TA1 to TAm and the unit transistors TB1 to TBn. As shown in FIG. 5, the transistors NDM1 having the wider body regions PBD are used as the unit transistors TA1 to TAm, and as shown in FIG. 4, the transistors NDM2 having the narrower body regions PBD are used as the unit transistors TB1 to TBn. Note that a pad PD in FIG. 12 corresponds to, for example, the pads PD1 and PD2 in FIG. 10.

According to the configuration, the negative surge generated at the node N1 of the drain can be absorbed by the unit transistors TA1 to TAm as the transistors NDM1 having the wider body regions PBD. The unit transistors TB1 to TBn as the transistors NDM2 having the narrower body regions PBD are provided in parallel to the unit transistors TA1 to TAm, and thus the driving capability necessary for driving the inductor can be obtained.

For example, the low-side transistors Q2 and Q4 of the bridge circuit 10 in FIG. 1 require a current supply capability for flowing the drive current necessary for driving the motor 100. However, when all of the unit transistors forming the transistors Q2 and Q4 are configured with the transistors NDM1 having the wider body regions PBD, the circuit area unnecessarily increases. Therefore, among the unit transistors forming the transistors Q2 and Q4, the unit transistors TA1 to TAm as the transistors NDM1 are used by the number necessary for absorbing the negative surge current. For the other transistors, the unit transistors TB1 to TBn as the transistors NDM2 having the smaller layout areas are used. According to the configuration, both the adverse effect due to the inflow of the negative surge current and the increase in the circuit area can be suppressed.

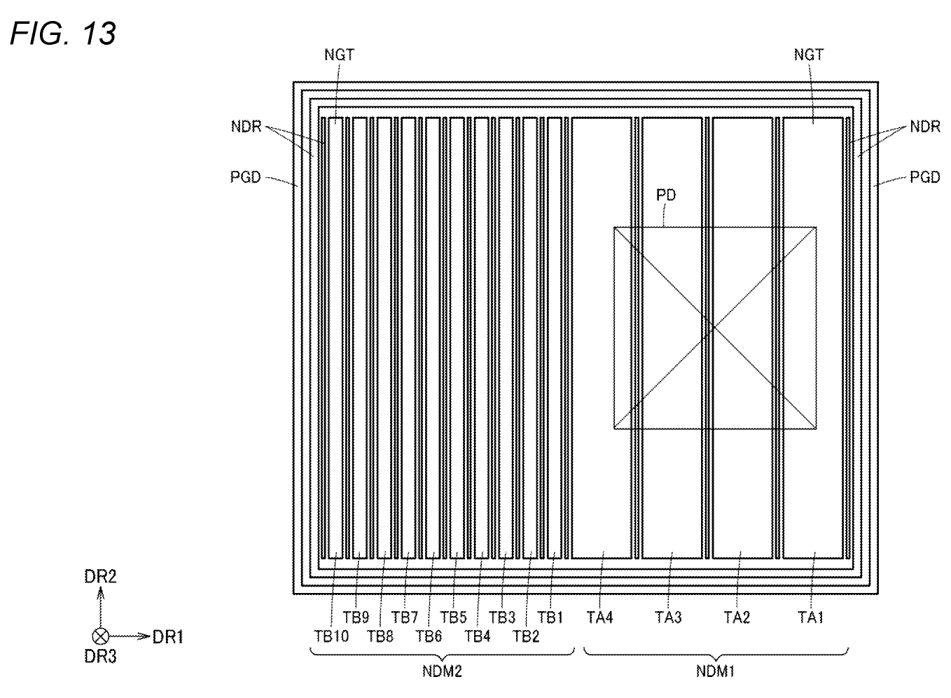

Further, in the present embodiment, as shown in FIG. 12, the pad PD to which the drain regions of the transistors NDM1 and the drain regions of the transistors NDM2 are coupled in common is provided. FIG. 13 is a plan view illustrating an arrangement example of the DMOS transistors NDM1 and NDM2 and the pad PD. As illustrated in FIG. 13, the pad PD is provided so as to overlap the transistors NDM1, but not to overlap the transistors NDM2 in the plan view. The plan view is, for example, a plan view in the direction orthogonal to the substrate PSB of the circuit device 2. For example, the low-side transistor Q2 includes the unit transistors TA1 to TA4 as the DMOS transistors NDM1 and the unit transistors TB1 to TB10 as the DMOS transistors NDM2. As illustrated in FIG. 13, the pad PD overlaps the unit transistors TA1 to TA4 as the transistors NDM1, but does not overlap the unit transistors TB1 to TB10 as the transistors NDM2 in the plan view.

According to the configuration, the negative surge generated in the drain region to which the pad PD is coupled can be efficiently absorbed by the unit transistors TA1 to TA4 as the transistors NDM1 disposed below the pad PD. For the unit transistors TB1 to TB10 not located under the pad PD, an increase in layout area of the circuit can be suppressed by using the transistors NDM2. For example, in the unit transistors TA1 to TA4 overlapping the pad PD in the plan view, the transmission of the negative surge is considered to be faster than that in the unit transistors TB1 to TB10 not overlapping the pad PD in the plan view. Therefore, the transistors NDM1 having the wider body regions PBD are used as the unit transistors TA1 to TA4 below the pad PD, and thus the negative surge can be efficiently absorbed by the body diodes of the body regions PBD. The transistors NDM2 having the narrower body regions PBD are used as the unit transistors TB1 to TB10 in which the transmission of the negative surge is considered to be slower than that of the unit transistors TA1 to TA4, and thus an increase in layout area of the transistor Q2 can be suppressed.

In FIG. 13, the guard region PGD is provided to surround the unit transistors TA1 to TA4 as the transistors NDM1 and the unit transistors TB1 to TB10 as the transistors NDM2. For example, the guard region PGD is provided in a ring shape. For example, as described with reference to FIGS. 4 and 5, the body diode formed with the PN junction between the P-type guard region PGD (PWL, PBL) and the N-type drift region NDFT also functions as a diode that absorbs a negative surge. Therefore, the guard region PGD is provided so as to surround the unit transistors TA1 to TA4 and TB1 to TB10, and thus the negative surge can be more effectively absorbed.

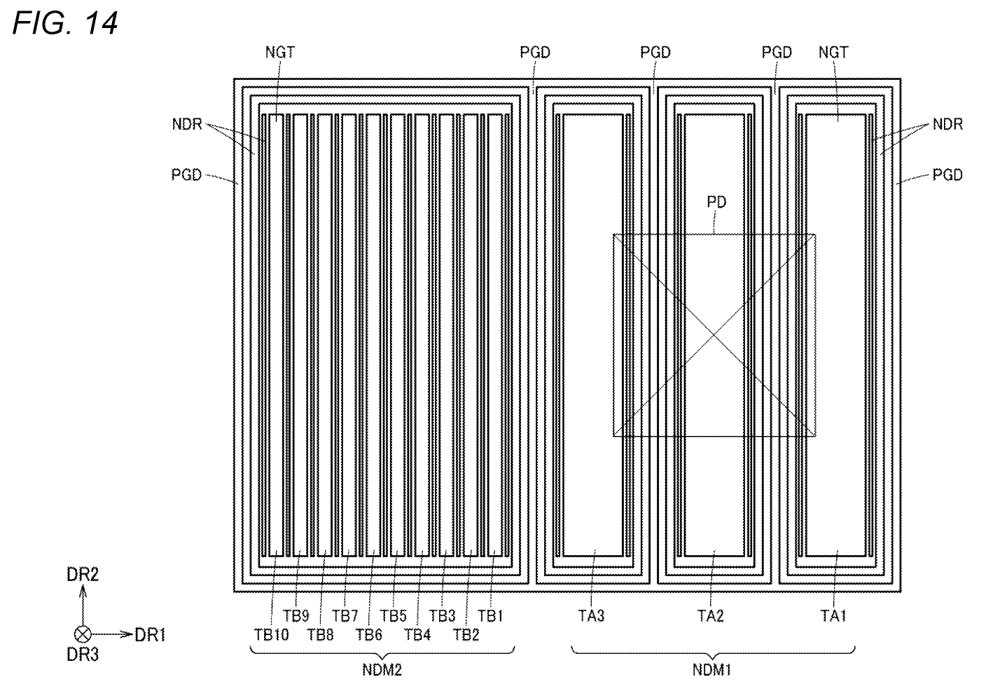

FIG. 14 is a plan view illustrating another arrangement example of the DMOS transistors NDM1 and NDM2 and the pad PD. For example, in the present embodiment, the P-type substrate PSB on which the transistors NDM1 and NDM2 are provided and the plurality of unit transistors TA1 to TA3 each of which is the DMOS transistor NDM1 are provided. The unit transistors TA1 to TA3 are the first unit transistors. In FIG. 14, the guard regions PGD that supply the potential to the P-type substrate PSB are provided between the adjacent unit transistors of the plurality of unit transistors TA1 to TA3. For example, the guard region PGD is provided between the unit transistor TA1 and the unit transistor TA2. The guard region PGD is also provided between the unit transistor TA2 and the unit transistor TA3. More specifically, the guard regions PGD are provided so as to surround the respective unit transistors TA1 to TA3. For example, the guard region PGD is provided to surround the unit transistor TA1, and the guard region PGD is provided to surround the unit transistor TA2. Further, the guard region PGD is provided to surround the unit transistor TA3. That is, the ring-shaped guard region PGD is provided so as to surround each unit transistor.

According to the configuration, the negative surge generated in the drain region can be absorbed by the body diodes formed with the wider body regions PBD of the unit transistors TA1 to TA3, and can also be absorbed by the body diodes formed with the guard regions PGD between the unit transistors. As a result, the negative surge can be absorbed more efficiently, and the adverse effect due to the inflow of the negative surge current can be further suppressed.

Further, in the present embodiment, the plurality of unit transistors TB1 to TB10 each of which is the DMOS transistor NDM2 are provided. In FIG. 14, the guard regions PGD that supply the potential to the P-type substrate PSB are provided so as to surround the plurality of unit transistors TB1 to TB10.

According to the configuration, the negative surge current generated in the drain regions of the unit transistors TB1 to TB10 can be absorbed by the body diodes of the narrower body regions PBD of the unit transistors TB1 to TB10, and can also be absorbed by the body diodes of the guard regions PGD surrounding the unit transistors TB1 to TB10. Therefore, the negative surge in the drain regions of the unit transistors TB1 to TB10 that are not disposed below the pad PD can also be effectively absorbed.

As described above, the circuit device of the present embodiment includes the N-type first DMOS transistor having the N-type first drain region coupled to the inductor, and the N-type second DMOS transistor. The first DMOS transistor includes the P-type first body region, the N-type first source region provided in the first body region, and the P-type first contact region provided in the first body region. The second DMOS transistor includes the P-type second body region, the N-type second source region provided in the second body region, and the P-type second contact region provided in the second body region. The width of the first body region in the channel length direction of the first DMOS transistor is wider than the width of the second body region in the channel length direction of the second DMOS transistor.

According to the present embodiment, the first DMOS transistor having the first drain region coupled to the inductor and the second DMOS transistor are provided in the circuit device. The width of the first body region in the channel length direction of the first DMOS transistor is wider than that of the second DMOS transistor. According to the configuration, even when a negative surge is generated in the first drain region of the first DMOS transistor due to the counter electromotive force of the inductor, the negative surge can be effectively absorbed by the body diode formed with the wider first body region. Accordingly, the occurrence of the adverse effect due to the negative surge can be suppressed.

In the present embodiment, the second DMOS transistor may be a transistor coupled in parallel to the first DMOS transistor.

According to the configuration, the negative surge can be absorbed by the first DMOS transistor having the wider first body region. The second DMOS transistor NDM2 having the narrower second body region is used as the transistor coupled in parallel to the first DMOS transistor, and thus an unnecessary increase in circuit area can be suppressed.

In the present embodiment, the plurality of first unit transistors each of which is the first DMOS transistor and the plurality of second unit transistors each of which is the second DMOS transistor may be provided. The plurality of first unit transistors and the plurality of second unit transistors may be coupled in parallel.

According to the configuration, the negative surge can be absorbed by the first unit transistors as the first DMOS transistors having the wider first body regions. The second unit transistors as the second DMOS transistors having the narrower second body regions are provided in parallel to the first unit transistors, and thus, for example, the driving capability necessary for driving the inductor can be obtained.

Further, in the present embodiment, the pad to which the first drain region of the first DMOS transistor and the second drain region of the second DMOS transistor are coupled in common may be provided, and the pad may overlap the first DMOS transistor and may not overlap the second DMOS transistor in the plan view.

According to the configuration, the negative surge generated in the drain region to which the pad is coupled can be efficiently absorbed by the first unit transistor as the first DMOS transistor disposed below the pad.

In the present embodiment, the P-type substrate on which the first DMOS transistor and the second DMOS transistor are provided and the plurality of first unit transistors each of which is the first DMOS transistor may be provided. The guard region that supplies the potential to the P-type substrate may be provided between the adjacent first unit transistors of the plurality of first unit transistors.

According to the configuration, the negative surge can be absorbed by the body diode of the wider first body region of the first unit transistor, and can also be absorbed by the body diode of the guard region between the first unit transistors.

In the present embodiment, the plurality of second unit transistors each of which is the second DMOS transistor are provided, and the guard region that supplies the potential to the P-type substrate may be provided so as to surround the plurality of second unit transistors.

According to the configuration, the negative surge generated in the drain region of the second unit transistor can also be absorbed by the body diode of the guard region surrounding the second unit transistor.

In the present embodiment, the width of the first contact region in the channel length direction of the first DMOS transistor may be wider than the width of the second contact region in the channel length direction of the second DMOS transistor.

As described above, the width of the first contact region of the first DMOS transistor is increased, and thus a large number of contacts can be disposed in the first contact region, and the negative surge can be more effectively absorbed.

In the present embodiment, the P-type substrate on which the first DMOS transistor and the second DMOS transistor are provided may be provided. The P-type first body region of the first DMOS transistor may be provided in the N-type first drift region provided between the first DMOS transistor and the P-type substrate. The P-type second body region of the second DMOS transistor may be provided in the N-type second drift region provided between the second DMOS transistor and the P-type substrate.

According to the configuration, the negative surge can be absorbed by the body diode formed with the PN junction between the P-type first body region and the N-type first drift region. Since the P-type first body region forming the body diode is wider in the channel length direction, the negative surge can be effectively absorbed.

In the present embodiment, the first DMOS transistor may be the low-side transistor of the bridge circuit that drives the inductor.

According to the configuration, the negative surge generated due to the counter electromotive force of the inductor driven by the bridge circuit can be effectively absorbed by the body diode formed with the first body region of the first DMOS transistor.

While the embodiment has been described in detail above, a person skilled in the art can readily understand that many modifications can be made without substantially departing from the novel matters and effects of the present disclosure. Therefore, all such modifications are within the scope of the present disclosure. For example, a term described at least once together with a different term having a broader meaning or the same meaning in the specification or the drawings can be replaced with the different term anywhere in the specification or the drawings. Further, all combinations of the present embodiment and the modifications are also included in the scope of the present disclosure. The configuration, operation, and arrangement of the circuit device, the structure of the transistor, and the like are not limited to those described in the present embodiment, and various modifications can be made.

What is claimed is:

1. A circuit device comprising:
an N-type first DMOS transistor having an N-type first drain region coupled to an inductor; and
an N-type second DMOS transistor, wherein
the first DMOS transistor includes
a P-type first body region,
an N-type first source region provided in the first body region, and
a P-type first contact region provided in the first body region,
the second DMOS transistor includes
a P-type second body region,
an N-type second source region provided in the second body region, and
a P-type second contact region provided in the second body region, and
a width of the first body region in a channel length direction of the first DMOS transistor is wider than a width of the second body region in the channel length direction of the second DMOS transistor.

2. The circuit device according to claim 1, wherein
the second DMOS transistor is a transistor coupled in parallel to the first DMOS transistor.

3. The circuit device according to claim 1, further comprising:
a plurality of first unit transistors each of which is the first DMOS transistor; and
a plurality of second unit transistors each of which is the second DMOS transistor, wherein
the plurality of first unit transistors and the plurality of second unit transistors are coupled in parallel.

4. The circuit device according to claim 1, further comprising a pad to which the first drain region of the first DMOS transistor and a second drain region of the second DMOS transistor are coupled in common, wherein
the pad overlaps the first DMOS transistor and does not overlap the second DMOS transistor in a plan view.

5. The circuit device according to claim 1, further comprising:
a P-type substrate on which the first DMOS transistor and the second DMOS transistor are provided; and
a plurality of first unit transistors each of which is the first DMOS transistor, wherein
a guard region that supplies a potential to the P-type substrate is provided between the adjacent first unit transistors of the plurality of first unit transistors.

6. The circuit device according to claim 5, further comprising a plurality of second unit transistors each of which is the second DMOS transistor, wherein
the guard region that supplies the potential to the P-type substrate is provided to surround the plurality of second unit transistors.

7. The circuit device according to claim 1, wherein
a width of the first contact region in the channel length direction of the first DMOS transistor is wider than a width of the second contact region in the channel length direction of the second DMOS transistor.

8. The circuit device according to claim 1, further comprising a P-type substrate on which the first DMOS transistor and the second DMOS transistor are provided, wherein
the P-type first body region of the first DMOS transistor is provided in an N-type first drift region provided between the first DMOS transistor and the P-type substrate, and
the P-type second body region of the second DMOS transistor is provided in an N-type second drift region provided between the second DMOS transistor and the P-type substrate.

9. The circuit device according to claim 1, wherein
the first DMOS transistor is a low-side transistor of
a bridge circuit that drives the inductor.
